(19) United States
(12) Patent Application Publication
(10) Pub. No.: US 2026/0191089 A1
(43) Pub. Date: Jul. 2, 2026

(54) SEMICONDUCTOR PACKAGE

(71) Applicant: SAMSUNG ELECTRONICS CO.,LTD, Suwon-si (JP)

(72) Inventor: HAJUNG LEE, Suwon-si (KR)

(73) Assignee: SAMSUNG ELECTRONICS CO.,LTD, Suwon-si (KR)

(21) Appl. No.: 19/278,193

(22) Filed: Jul. 23, 2025

(30) Foreign Application Priority Data
Dec. 26, 2024 (KR) 10-2024-0197750

(51) Int. Cl. H01L 23/29; H01L 21/56; H01L 21/683; H01L 23/00; H01L 23/31; H01L 25/18; H10B 80/00; H10D 80/30

(52) U.S. Cl. CPC H10W 74/473; H10D 80/30; H10W 74/121; H10W 74/43; H10W 90/00; H10B 80/00; H10P 72/74; H10W 72/0198; H10W 72/877; H10W 74/016; H10W 74/15; H10W 90/20; H10W 90/297; H10W 90/722; H10W 90/732

(57) ABSTRACT

A semiconductor package includes a base die, a plurality of core dies on the base die, a first molding structure on the base die and at least partially covering side surfaces of the plurality of core dies, and a second molding structure on the first molding structure, where the first molding structure includes a first filler, the second molding structure includes a second filler that is different from the first filler, a hardness of the first filler is greater than a hardness of the second filler, and a side surface of the first molding structure is aligned with a side surface of the second molding structure.

### CROSS-REFERENCE TO RELATED APPLICATION

This application is based on and claims priority under 35 U.S.C § 119 to Korean Patent Application No. 10-2024-0197750, filed on Dec. 26, 2024, in the Korean Intellectual Property Office, the disclosure of which is incorporated by reference herein in its entirety.

### BACKGROUND

The present disclosure relates to a semiconductor package, and more particularly, to a semiconductor package including a plurality of stacked semiconductor chips.

The demand for high-performance electronic devices has increased as the electronic industry has rapidly developed. Therefore, the need for methods to arrange a plurality of semiconductor chips to achieve higher performance is increasing. Accordingly, a semiconductor package in which a plurality of semiconductor chips having through electrodes are stacked in a vertical direction has been proposed.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor package that may provide improved thermal radiation and increased process stability.

Additional aspects will be set forth in part in the description which follows and, in part, will be apparent from the description, or may be learned by practice of the presented embodiments.

According to an aspect of an example embodiment, a semiconductor package may include a base die, a plurality of core dies on the base die, a first molding structure on the base die and at least partially covering side surfaces of the plurality of core dies, and a second molding structure on the first molding structure, where the first molding structure includes a first filler, the second molding structure includes a second filler that is different from the first filler, a hardness of the first filler is greater than a hardness of the second filler, and a side surface of the first molding structure is aligned with a side surface of the second molding structure.

According to an aspect of an example embodiment, a semiconductor package may include a base die, a plurality of core dies on the base die, a first molding structure on the base die and at least partially covering side surfaces of the plurality of core dies, and a second molding structure on the first molding structure, where the first molding structure includes a first filler, the second molding structure includes a second filler that is different from the first filler, a side surface of the first molding structure is exposed, and a thermal conductivity of the first filler is greater than a thermal conductivity of the second filler.

According to an aspect of an example embodiment, a semiconductor package may include a package substrate, an interposer substrate on the package substrate, a logic chip on the interposer substrate, and a plurality of chip stack structures spaced apart in a first direction on the logic chip, the first direction being parallel to an upper surface of the package substrate, where each chip stack structure of the plurality of chip stack structures may include a base die, a plurality of core dies on the base die, a first molding structure on the base die and at least partially covering side surfaces of the plurality of core dies, and a second molding structure on the first molding structure, and where the first molding structure include at least one of metal oxide and metal nitride, and the second molding structure include silicon oxide.

According to an aspect of an example embodiment, a method of fabricating a semiconductor package may include providing a wafer on a carrier substrate, bonding a first core die to the wafer, stacking a plurality of second core dies on the first core die, forming a first molding structure on the wafer, the first molding structure including a first filler, and forming a second molding structure on an upper surface of the first molding structure, the second molding structure including a second filler that is different from the first molding structure, where a hardness of the first filler is greater than a hardness of the second filler, and the method may include performing a grinding process on an upper portion of the second molding structure, turning the wafer, the core dies, and the molding structure upside down, removing the carrier substrate, and performing a sawing process on the wafer, and the molding structures.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a cross-sectional view illustrating a semiconductor package according to one or more embodiments;

FIG. 2 is a cross-sectional view illustrating a semiconductor package according to one or more embodiments;

FIGS. 3, 4, 5, 6, 7, 8, and 9 are cross-sectional views illustrating a method of fabricating a semiconductor package according to one or more embodiments;

FIG. 10 is a plan view illustrating a semiconductor package according to one or more embodiments; and

FIG. 11 is a cross-sectional view taken along line A-A′ of FIG. 10 according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

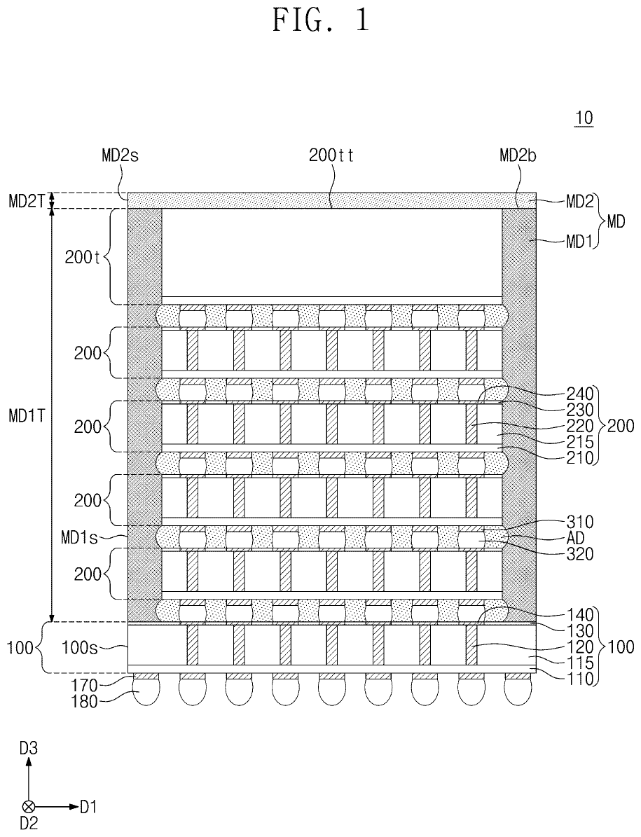

FIG. 1 is a cross-sectional view illustrating a semiconductor package according to one or more embodiments.

Referring to FIG. 1, a semiconductor package 10 according to one or more embodiments may be, for example, a high bandwidth memory (HBM). The semiconductor package 10 may be referred to as a chip stack structure.

The semiconductor package 10 may include a base die 100, a plurality of core dies 200, and a molding structure MD.

The base die 100 may be provided on a lower portion of the semiconductor package 10. The base die 100 may be referred to as a logic die, a logic chip, a base chip, a buffer chip, a buffer die, or a memory controller. The base die 100 may serve as a logic chip that increases date delivery efficiency and decreases power consumption.

A first direction D1 may be defined to refer to a direction parallel to an upper surface of the base die 100. A second direction D2 may be defined to refer to a direction parallel to the upper surface of the base die 100 and intersecting the first direction D1. A third direction D3 may be defined to refer to a direction perpendicular to the upper surface of the base die 100.

The base die 100 may include a first semiconductor substrate 115, a first lower dielectric layer 110, a first through electrode 120, a first upper dielectric layer 130, and a first pad 140.

The first semiconductor substrate 115 may include a semiconductor material, such as silicon and germanium. The first through electrode 120 may penetrate the first semiconductor substrate 115. The first through electrode 120 may be provided in plural, and the plurality of first through electrodes 120 may be spaced apart from each other in the first direction D1. The first through electrode 120 may include a conductive material, such as copper. The first through electrode 120 and the first semiconductor substrate 115 may be provided therebetween with a diffusion barrier pattern including tantalum nitride (TaN), tantalum (Ta), titanium nitride (TiN), or tungsten (W).

The first lower dielectric layer 110 may be disposed on a lower surface of the first semiconductor substrate 115. The first lower dielectric layer 110 may be provided therein with a wiring pattern and a circuit layer.

The first upper dielectric layer 130 may be disposed on an upper surface of the first semiconductor substrate 115. The first pads 140 may be provided in the first upper dielectric layer 130. The first lower dielectric layer 110 and the first upper dielectric layer 130 may include, for example, at least one of silicon oxide (SiO₂), silicon nitride (Si₃N₄), and silicon oxynitride (SiOₓN_{y}).

A plurality of conductive pads 170 may be provided on a lower surface of the base die 100. First connection terminals 180 may be correspondingly provided on lower surfaces of the conductive pads 170. The first connection terminals 180 may include solder balls or solder bumps. The first connection terminals 180 may be an alloy including at least one selected from silver, copper, and tin.

The plurality of core dies 200 may be disposed on the base die 100. Each of the core dies 200 may be a memory chip. The core die 200 may be, for example, one of a dynamic random access memory (RAM) (DRAM), static RAM (SRAM), and NAND Flash.

Each of the core dies 200 may include a second semiconductor substrate 215, a second lower dielectric layer 210, a second through electrode 220, a second upper dielectric layer 230, and a second pad 240.

The second semiconductor substrate 215 may include a semiconductor material, such as silicon (Si). The second through electrode 220 may penetrate the second semiconductor substrate 215. The second through electrode 220 may be provided in plural, and the plurality of second through electrodes 220 may be spaced apart from each other in the first direction D1. The second through electrode 220 may include a conductive material, such as copper. The second through electrode 220 and the second semiconductor substrate 215 may be provided therebetween with a diffusion barrier pattern including tantalum nitride (TaN), tantalum (Ta), titanium nitride (TiN), or tungsten (W).

The second lower dielectric layer 210 may be disposed on a lower surface of the second semiconductor substrate 215. The second lower dielectric layer 210 may be provided therein with a wiring pattern and a circuit layer. The second upper dielectric layer 230 may be disposed on an upper surface of the second semiconductor substrate 215. The second pads 240 may be provided in the second upper dielectric layer 230. The second lower dielectric layer 210 and the second upper dielectric layer 230 may include, for example, at least one selected from silicon oxide (SiO₂), silicon nitride (Si₃N₄), and silicon oxynitride (SiOₓN_{y}).

A thickness of the second semiconductor substrate 215 included in a core die 200t positioned at the top of the plurality of core dies 200 (e.g., an uppermost core die 200t) may be greater than that of the second semiconductor substrate 215 included in each of remaining core dies 200. Unlike the other core dies 200, the uppermost core die 200t may include no through electrode.

Third pads 310 may be provided on a lower surface of each of the plurality of core dies 200. Chip connection terminals 320 may be correspondingly provided on the third pads 310. For example, one or more of the chip connection terminals 320 may be disposed on the base die 100 and the core die 200. One or more of the chip connection terminals 320 may be disposed between the core dies 200 and 200t that are adjacent to each other. For example, one or more of the chip connection terminals 320 may electrically connect the base die 100 and the core die 200 to each other. One or more of the chip connection terminals 320 may electrically connect the core dies 200 and 200t to each other. The chip connection terminals 320 may each be an alloy including at least one selected from silver, copper, and tin.

Non-conductive layers AD may be disposed between the base die 100 and the core die 200 and between neighboring core dies 200. The non-conductive layer AD may surround side surfaces of the chip connection terminals 320. The non-conductive layers AD may include a non-conductive film (NCF) or a non-conductive paste (NCP).

The molding structure MD may be disposed on the base die 100. The molding structure MD may include a first molding structure MD1 and a second molding structure MD2 on the first molding structure MD1. The second molding structure MD2 may be spaced apart in the third direction D3 from the base die 100.

The first molding structure MD1 may be disposed on the upper surface of the base die 100. The first molding structure MD1 may cover side surfaces of the core dies 200 and 200t. An upper surface of the first molding structure MD1 may be located at a level substantially the same as that of an upper surface 200tt of the uppermost core die 200t. A lower surface MD2b of the second molding structure MD2 may contact the upper surface 200tt of the uppermost core die 200t and the upper surface of the first molding structure MD1. A side surface MD1s of the first molding structure MD1 may be aligned with a side surface MD2s of the second molding structure MD2 in the first direction D1 and the second direction D2. For example, the side surface MD1s of the first molding structure MD1 and the side surface MD2s of the second molding structure MD2 may be exposed on their respective side surfaces. The side surface MD1s of the first molding structure MD1 may be aligned with a side surface 100s of the base die 100. A thickness MD1T of the first molding structure MD1 may be greater than a thickness MD2T of the second molding structure MD2. For example, the thickness MD2T of the second molding structure MD2 may be equal to or less than about 10 μm.

The first molding structure MD1 may include a cross-linked thermosetting resin matrix and a first filler dispersedly embedded in the resin matrix. The second molding structure MD2 may include a cross-linked thermosetting resin matrix and a second filler dispersedly embedded in the resin matrix. For example, the first filler may include at least one of aluminum oxide, aluminum nitride, and magnesium oxide. The second filler may include, for example, silicon oxide.

The second filler may have a fracture toughness less than that of the first filler. For example, the fracture toughness of the first filler may range from about 3 MPa·m^{0.5} to about 5 MPa·m^{0.5}, and the fracture toughness of the second filler may range from about 0.5 MPa·m^{0.5} to about 1 MPa·m^{0.5}. The first filler may have hardness greater than that of the second filler. For example, the hardness of the first filler may range from about 8 to about 9, and the hardness of the second filler may range from about 6 to about 7. The hardness may correspond to a hardness scale known as ‘Mohs hardness scale’. That is, the hardness of 6, 7, 8, 9, etc., may correspond to the Mohs hardness scale.

The first filler may have a dielectric constant greater than that of the second filler. For example, the first filler may have a dielectric constant of 8 to 10, and the second filler may have a dielectric constant of 3.5 to 4.5. The first filler may have a thermal conductivity greater than that of the second filler. For example, the thermal conductivity of the first filler may range from about 30 W/m·K to about 35 W/m·K, and the thermal conductivity of the second filler may range from about 0.8 W/m·K to about 1.5 W/m·K.

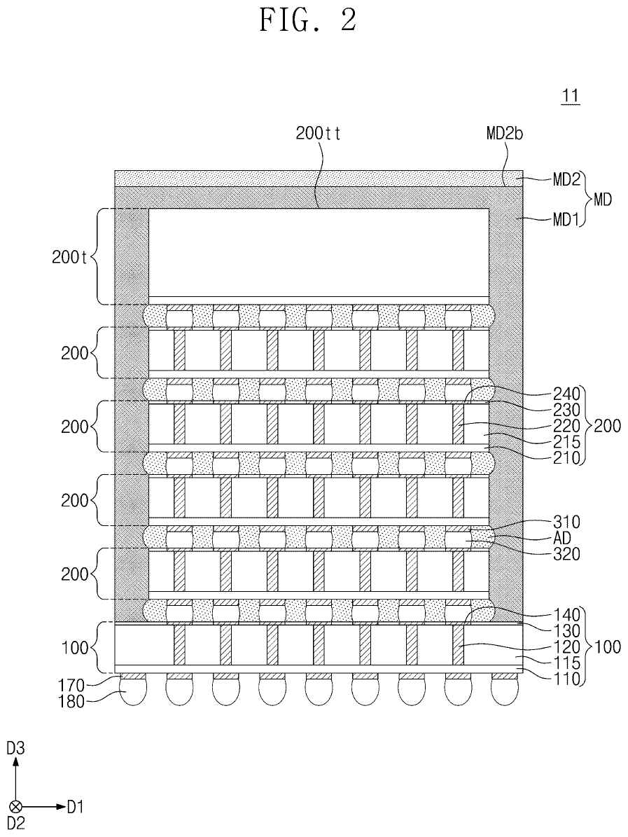

FIG. 2 is a cross-sectional view illustrating a semiconductor package according to one or more embodiments. Description of aspects that are the same as or similar to those described above may be omitted.

Referring to FIG. 2, in a semiconductor package 11 according to one or more embodiments, the second molding structure MD2 may be spaced apart in the third direction D3 from the upper surface 200tt of the uppermost core die 200t. For example, the lower surface MD2b of the second molding structure MD2 may be located at a level higher than that of the upper surface 200tt of the uppermost core die 200t.

In this case, the first molding structure MD1 may fill the space between the upper surface 200tt of the uppermost core die 200t and the lower surface MD2b of the second molding structure MD2.

A semiconductor package according to one or more embodiments may include a first molding structure that is disposed on an upper surface of a base die to cover side surfaces of core dies, and may also include a second molding structure disposed on the first molding structure. The first molding structure and the second molding structure may respectively include a first filler and a second filler. The first filler may have a thermal conductivity greater than that of the second filler. Thus, even when heat is generated from the base die and the core dies, the first filler may cause the semiconductor package to have an improvement in thermal radiation. In addition, the second filler may have a fracture toughness and a hardness less than those of the first filler. Accordingly, in a grinding process for a molding structure, abrasion of a grinding wheel may be alleviated to improve stability and efficiency of fabrication process for the semiconductor package.

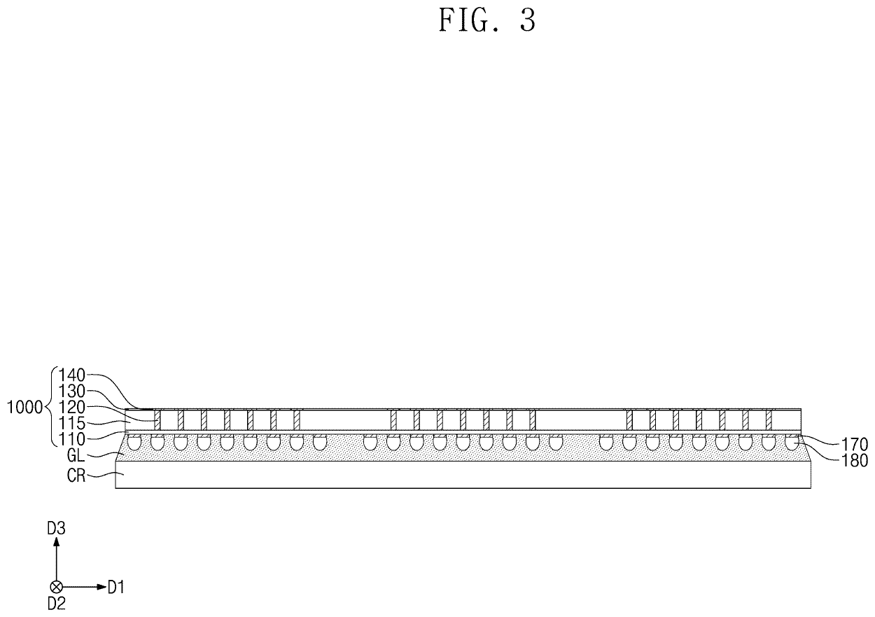

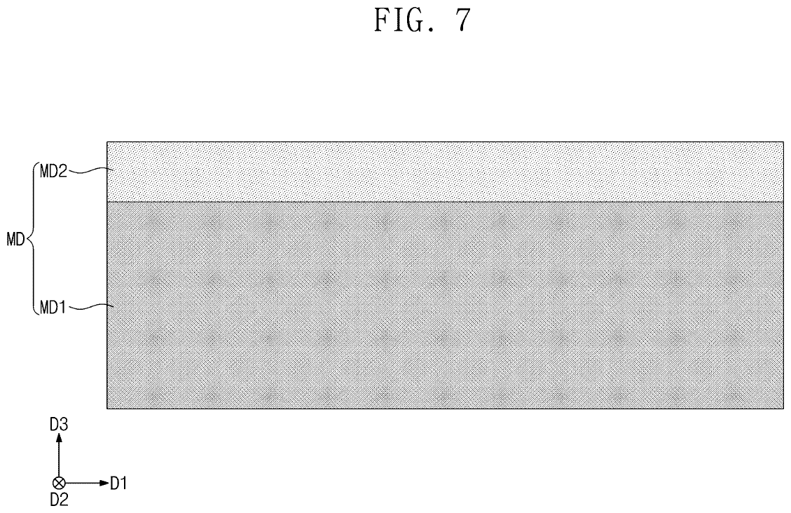

FIGS. 3, 4, 5, 6, 7, 8, and 9 are cross-sectional views illustrating a method of fabricating a semiconductor package according to one or more embodiments. FIG. 7 depicts in detail a molding layer MD formed according to one or more embodiments.

Referring to FIG. 3, a wafer 1000 may be provided. The wafer 1000 may include a first lower dielectric layer 110, a first semiconductor substrate 115, first through electrodes 120 that penetrate the first semiconductor substrate 115, a first upper dielectric layer 130, and a first pad 140. Conductive pads 170 may be provided on a lower surface of the wafer 1000, and first connection terminals 180 may be provided on the conductive pads 170.

The wafer 1000 may be provided on a carrier substrate CR. The carrier substrate CR may be a dielectric substrate including glass or polymer or may be a conductive substrate including metal. An adhesive member GL may be provided on an upper surface of the carrier substrate CR. The adhesive member GL may surround the first connection terminals 180. The wafer 1000 may be attached through the adhesive member GL to the carrier substrate CR.

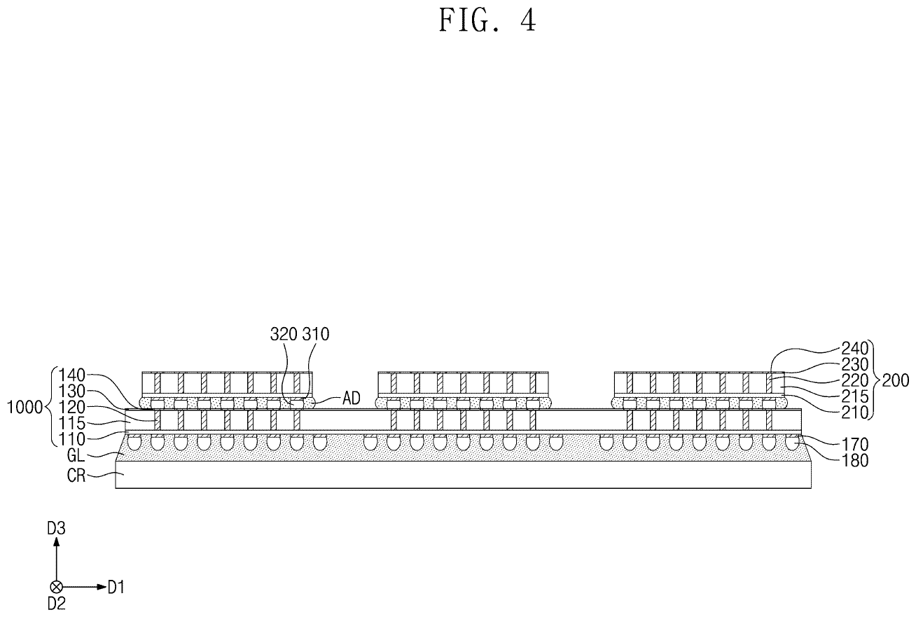

Referring to FIG. 4, a plurality of core dies 200 may be bonded to the wafer 1000. The core dies 200 may be spaced apart from each other in the first direction D1. Each of the core dies 200 may include a second semiconductor substrate 215, a second lower dielectric layer 210, a second through electrode 220, a second upper dielectric layer 230, and a second pad 240. Third pads 310 may be correspondingly provided on lower surfaces of the core dies 200, and chip connection terminals 320 may be correspondingly provided on the third pads 310.

Non-conductive layers AD may be provided between the wafer 1000 and the core dies 200. The non-conductive layers AD may surround side surfaces of the chip connection terminals 320. The non-conductive layers 410 may include, for example, an NCF or an NCP.

For example, a thermocompression process may be employed to bond the core dies 200 to the wafer 1000. The thermocompression process may cause the non-conductive layers AD to outwardly protrude from side surfaces of the core dies 200.

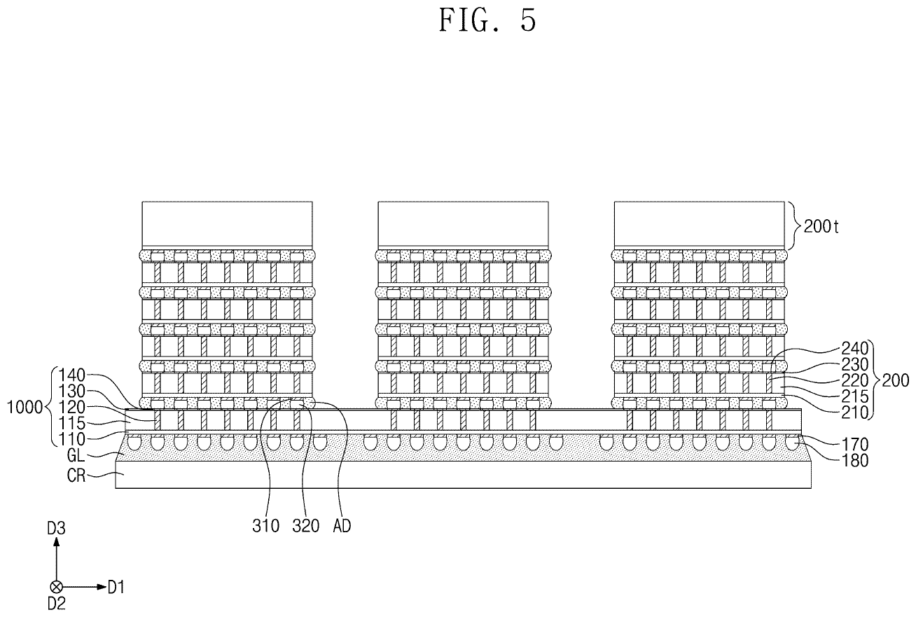

Referring to FIG. 5, a plurality of core dies 200 (i.e., additional core dies 200) may be provided along the third direction D3. The plurality of core dies 200 may be stacked along the third direction D3 on a lowermost core die 200 through a process substantially the same as or similar to the process of FIG. 4. An uppermost core die 200t may include no through electrode.

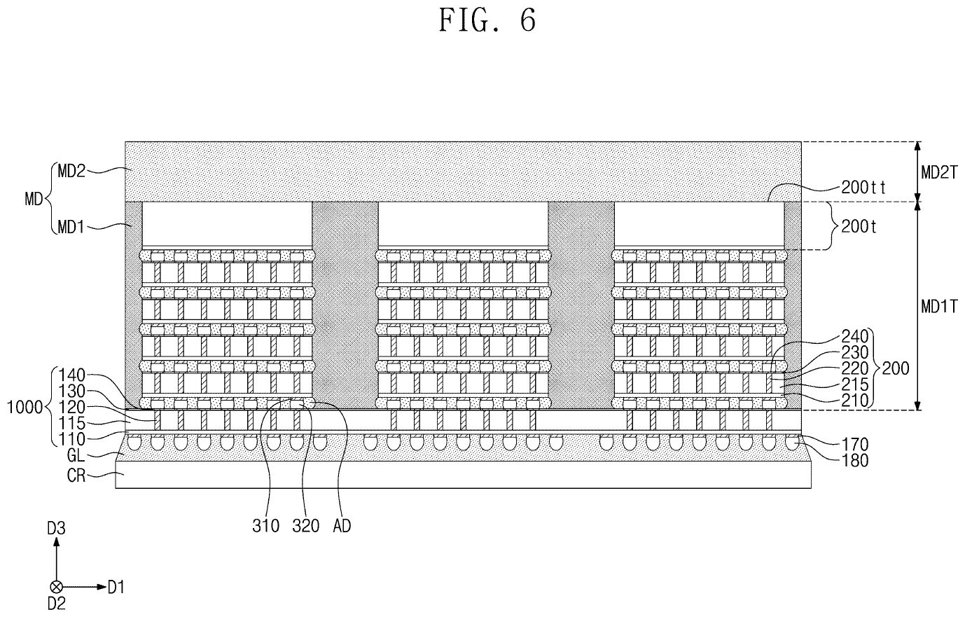

Referring to FIGS. 6 and 7, a molding structure MD may be formed on the wafer 1000. The formation of the molding structure MD may include forming a first molding structure MD1 and forming a second molding structure MD2 on the first molding structure MD1.

For example, a first epoxy molding compound may be melted and cured to form the first molding structure MD1. The first epoxy molding compound may include a molding compound epoxy resin and a first filler. The first filler may include, for example, at least one of aluminum oxide, aluminum nitride, and magnesium oxide. The first epoxy molding compound may be provided, for example, in the form of a sheet. On an upper surface of the wafer 1000, the first molding structure MD1 may surround the side surfaces of the core dies 200.

For example, a second epoxy molding compound may be melted and cured to form the second molding structure MD2. The second epoxy molding compound may include a molding compound epoxy resin and a second filler. The second filler may include, for example, silicon oxide. The second epoxy molding compound may be provided, for example, in the form of a sheet. The second molding structure MD2 may be provided on the first molding structure MD1. The second molding structure MD2 may contact an upper surface of the first molding structure MD1 and an upper surface 200tt of the uppermost core die 200t.

A thickness MD1T of the first molding structure MD1 may be greater than a thickness MD2T of the second molding structure MD2. For example, the thickness MD2T of the second molding structure MD2 may be about 10% to about 15% of the thickness MD1T of the first molding structure MD1. The second molding structure MD2 may have a fracture toughness less than that of the first molding structure MD1.

For example, as shown in FIG. 7, the molding structure MD formed according to one or more embodiments may include a plurality of molding structures containing different materials from each other. The plurality of molding structures included in the molding structure MD may be different in terms of fracture toughness and thermal conductivity. Characteristics of the molding structure MD according to one or more embodiments may be applied to various semiconductor packages without being limited to the chip stack structure 10 discussed in FIG. 1.

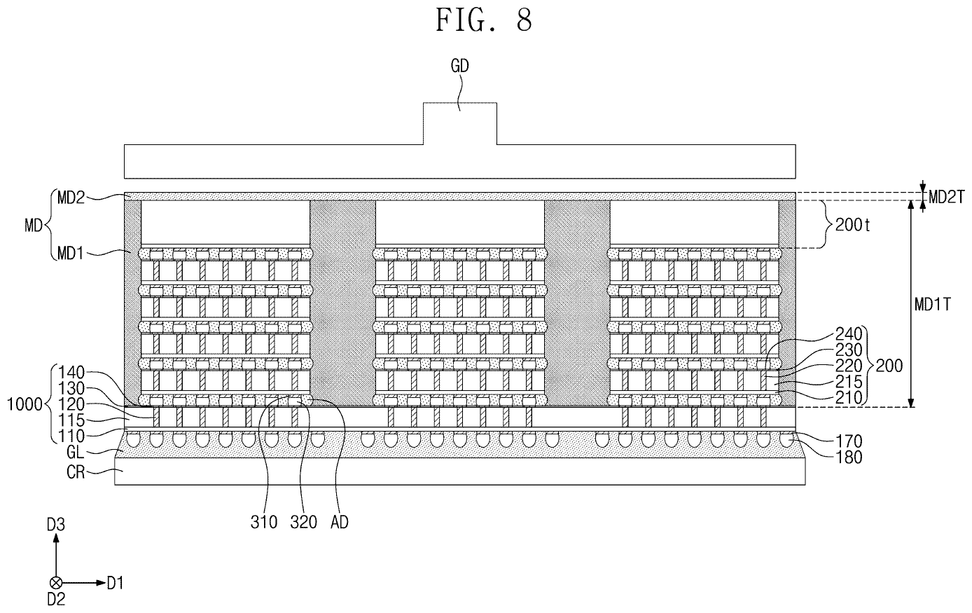

Referring to FIG. 8, a grinding process may be performed on a partial upper portion of the second molding structure MD2. For example, a grinding wheel GD may be utilized to perform the grinding process. As a result of the grinding process, the second molding structure MD2 may have a reduced thickness in the third direction D3. For example, after the grinding process is performed, the thickness MD2T of the second molding structure MD2 may be equal to or less than about 10 μm. Because the second filler may have a fracture toughness and a hardness less than those of the first filler, abrasion of a grinding wheel GD may be alleviated.

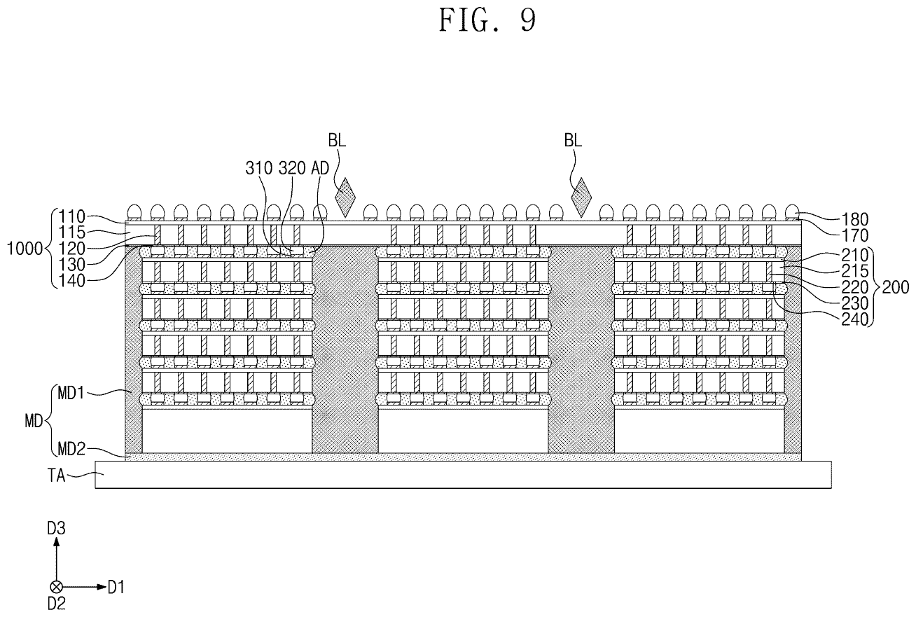

Referring to FIG. 9, the wafer 1000, the core dies 200, the first molding structure MD1, and the second molding structure MD2 may be turned upside down. The carrier substrate CR and the adhesive member GL may be removed, and the lower surface of the wafer 1000 may be exposed. A tape TA may be provided on the second molding structure MD2.

A sawing process may be performed on the wafer 1000, the first molding structure MD1, and the second molding structure MD2. For example, a sawing blade BL may be utilized to perform the sawing process. As a result of the sawing process, the wafer 1000 may be formed into a plurality of base dies 100 discussed in FIG. 1.

Afterwards, referring back to FIG. 1, the base dies 100, the core dies 200, and the molding structure MD may be turned upside down, and the tape TA may be removed to eventually fabricate a semiconductor package 10 according to one or more embodiments.

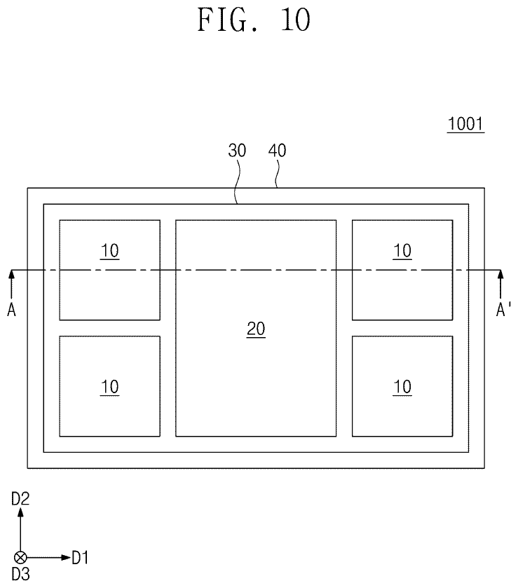

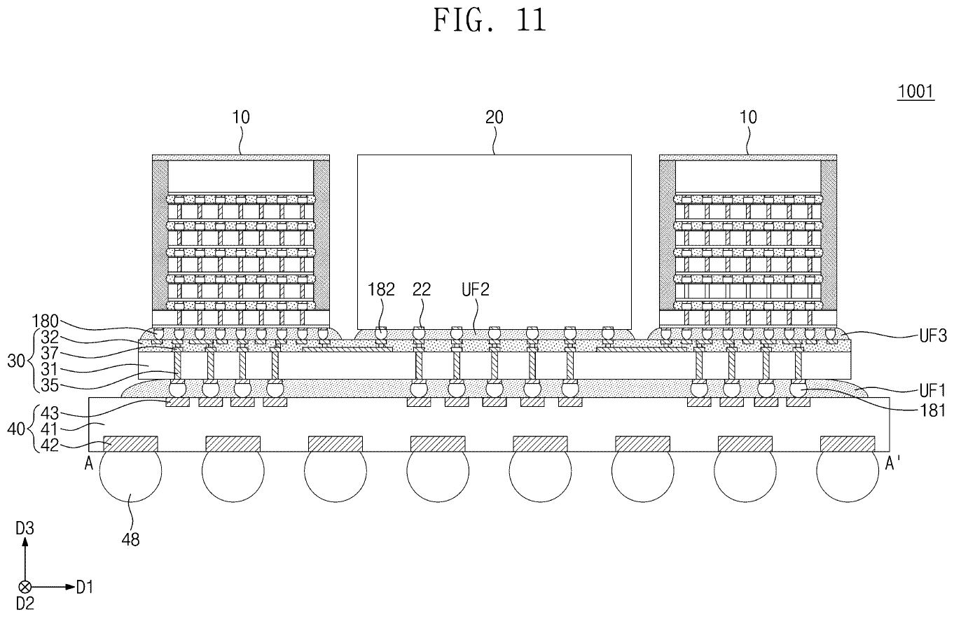

10 is a plan view illustrating a semiconductor package according to one or more embodiments. FIG. 11 is a cross-sectional view taken along line A-A′ of FIG. 10 according to one or more embodiments.

Referring to FIGS. 10 and 11, a semiconductor package 1001 according to one or more embodiments may include a package substrate 40, an interposer substrate 30, a logic chip 20, and a plurality of chip stack structures 10. The chip stack structure 10 of FIGS. 10 and 11 may correspond to, for example, the semiconductor package 10 according to some embodiments discussed in FIG. 1.

The package substrate 40 may be, for example, a printed circuit board (PCB). Alternatively, the package substrate 40 may have a structure in which at least one dielectric layer and at least one wiring layer are alternately stacked. The package substrate 40 may include a plurality of upper substrate pads 43 on an upper surface thereof and a plurality of lower substrate pads 42 on a lower surface thereof.

External connection terminals 48 may be correspondingly disposed on the lower substrate pads 42. The external connection terminals 48 may be electrically connected through the lower substrate pads 42 to the upper substrate pads 43 and the wiring layer in the package substrate 40.

The external connection terminals 48 may include solder balls or solder bumps. The external connection terminals 48 may each be an alloy including at least one of silver, copper, and tin.

The interposer substrate 30 may be disposed on the package substrate 40. The interposer substrate 30 may include an interposer core substrate 31, interposer vias 35, an interposer dielectric layer 32, and interposer wiring patterns 37.

The interposer core substrate 31 may be a semiconductor substrate, for example, a silicon (Si) substrate. The interposer vias 35 may penetrate the interposer core substrate 31. The interposer vias 35 may be provided in plural along the first direction D1.

The interposer dielectric layer 32 may be disposed on the interposer core substrate 31. The interposer dielectric layer 32 may include the interposer wiring patterns 37 therein. The interposer wiring patterns 37 may be electrically connected to the interposer vias 35. The interposer dielectric layer 32 may include a dielectric material, such as silicon oxide and silicon nitride. The interposer wiring patterns 37 may include a metallic material, such as copper.

Second connection terminals 181 and a first underfill layer UF1 may be disposed between the package substrate 40 and the interposer substrate 30. The first underfill layer UF1 may fill a space between the package substrate 40 and the interposer substrate 30, and may surround a side surface of each of the second connection terminals 181. The second connection terminals 181 may include a conductive material, such as solder. The first underfill layer UF1 may include, for example, an epoxy resin.

The logic chip 20 and the plurality of chip stack structures 10 may be disposed on the interposer substrate 30. For example, the logic chip 20 may be positioned on a central portion of the interposer substrate 30. The chip stack structures 10 may be spaced apart in the first direction D1 from each other across the logic chip 20. As illustrated in FIG. 10, two chip stack structures 10 may be disposed adjacent to one side surface of the logic chip 20, and another two chip stack structures 10 may be disposed on an opposing side surface of the logic chip 20. The chip stack structures 10 disposed adjacent to each other may be spaced apart along the second direction D2 from each other. However, embodiments are not limited thereto, and an arrangement of the logic chip 20 and the chip stack structures 10 may vary.

The logic chip 20 may be, for example, one of a central processing unit (CPU), a graphic processing unit (GPU), and an application specific integrated circuit (ASIC). The logic chip 20 may transceive signals with the chip stack structure 10. The logic chip 20 may include chip pads 22 on a lower portion thereof. Third connection terminals 182 may be correspondingly disposed on the chip pads 22. The third connection terminals 182 may include a conductive material, such as solder.

The first connection terminals 180 of the chip stack structure 10 and the third connection terminals 182 of the logic chip 20 may contact pads on an upper surface of the interposer substrate 30. A second underfill layer UF2 may be disposed between the logic chip 20 and the interposer substrate 30. The second underfill layer UF2 may fill between the third connection terminals 182. A third underfill layer UF3 may be interposed between the chip stack structure 10 and the interposer substrate 30. The third underfill layer UF3 may fill between the first connection terminals 180. The second underfill layer UF2 and the third underfill layer UF3 may include, for example, an epoxy resin composition.

A semiconductor package according to one or more embodiments may include a first molding structure that is disposed on a upper surface of a base die to cover side surfaces of core dies, and may also include a second molding structure disposed on the first molding structure. The first molding structure and the second molding structure may respectively include a first filler and a second filler. The second filler may have a fracture toughness and a hardness less than those of the first filler. Accordingly, in a grinding process for a molding structure, abrasion of a grinding wheel may be alleviated to improve stability and efficiency of fabrication process for the semiconductor package.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is

1. A semiconductor package comprising:
a base die;
a plurality of core dies on the base die;
a first molding structure on the base die and at least partially covering side surfaces of the plurality of core dies; and
a second molding structure on the first molding structure,
wherein the first molding structure comprises a first filler,
wherein the second molding structure comprises a second filler that is different from the first filler,
wherein a hardness of the first filler is greater than a hardness of the second filler, and
wherein a side surface of the first molding structure is aligned with a side surface of the second molding structure.

2. The semiconductor package of claim 1, wherein a fracture toughness of the second filler is less than a fracture toughness of the first filler.

3. The semiconductor package of claim 2, wherein the fracture toughness of the first filler is in a range of 3 MPa·m^{0.5} to 5 MPa·m^{0.5}, and
wherein the fracture toughness of the second filler is in a range of 0.5 MPa·m^{0.5} to 1 MPa·m^{0.5}.

4. The semiconductor package of claim 1, wherein the hardness of the first filler is in a range of 8 to 9, and
wherein the hardness of the second filler is in a range 6 to 7.

5. The semiconductor package of claim 1, wherein the plurality of core dies comprises an uppermost core die, and
wherein a lower surface of the second molding structure contacts an upper surface of the uppermost core die and an upper surface of the first molding structure.

6. The semiconductor package of claim 1, wherein the plurality of core dies comprises an uppermost core die, and
wherein a lower surface of the second molding structure is spaced apart from a upper surface of the uppermost core die.

7. The semiconductor package of claim 6, wherein the first molding structure is between the upper surface of the uppermost core die and the lower surface of the second molding structure.

8. The semiconductor package of claim 1, wherein a dielectric constant of the first filler is greater than a dielectric constant of the second filler.

9. The semiconductor package of claim 1, wherein the first filler comprises at least one of aluminum oxide, aluminum nitride, and magnesium oxide, and
wherein the second filler comprises silicon oxide.

10. A semiconductor package comprising:
a base die;
a plurality of core dies on the base die;
a first molding structure on the base die and at least partially covering side surfaces of the plurality of core dies; and
a second molding structure on the first molding structure,
wherein the first molding structure comprises a first filler,
wherein the second molding structure comprises a second filler that is different from the first filler,
wherein a side surface of the first molding structure is exposed, and
wherein a thermal conductivity of the first filler is greater than a thermal conductivity of the second filler.

11. The semiconductor package of claim 10, wherein a thickness of the first molding structure is greater than a thickness of the second molding structure, and
wherein the thickness of the second molding structure is equal to or less than 10 μm.

12. The semiconductor package of claim 10, wherein the thermal conductivity of the first filler is in a range of 30 W/m·K to 35 W/m·K, and
wherein the thermal conductivity of the second filler is in a range of 0.8 W/m·K to 1.5 W/m·K.

13. The semiconductor package of claim 10, wherein the second molding structure is vertically spaced apart from the base die.

14. The semiconductor package of claim 10, wherein the plurality of core dies comprises an uppermost core die, and
wherein a lower surface of the second molding structure is at a level higher than a level of an upper surface of the uppermost core die.

15. A semiconductor package comprising:
a package substrate;
an interposer substrate on the package substrate;
a logic chip on the interposer substrate; and
a plurality of chip stack structures spaced apart in a first direction on the logic chip, the first direction being parallel to an upper surface of the package substrate,
wherein each chip stack structure of the plurality of chip stack structures comprises:
a base die;
a plurality of core dies on the base die;
a first molding structure on the base die and at least partially covering side surfaces of the plurality of core dies; and
a second molding structure on the first molding structure,
wherein the first molding structure comprises at least one of metal oxide and metal nitride, and
wherein the second molding structure comprises silicon oxide.

16. The semiconductor package of claim 15, wherein a lower surface of the second molding structure contacts an upper surface of the first molding structure.

17. The semiconductor package of claim 15, wherein a thickness of the first molding structure is greater than a thickness of the second molding structure, and
wherein the thickness of the second molding structure is equal to or less than about 10 μm.

18. The semiconductor package of claim 15, wherein the second molding structure is vertically spaced apart from the base die.

19. The semiconductor package of claim 15, wherein a side surface of the first molding structure is aligned with a side surface of the base die.

20. The semiconductor package of claim 15, wherein the first molding structure comprises at least one of aluminum oxide, aluminum nitride, and magnesium oxide.
